(19) United States
(12) Patent Application Publication
(10) Pub. No.: US 2010/0123506 A1
(43) Pub. Date: May 20, 2010

(54) MULTISTAGE LEVEL TRANSLATOR

(76) Inventors: Cung Vu, San Jose, CA (US); Dung Tran, Milpitas, CA (US)

Correspondence Address: TRACY PARRIS, 6201 MAGIC CANYON ROAD, RAPID CITY, SD, 57702, US

(21) Appl. No.: 12/275,109

(22) Filed: Nov. 20, 2008

(51) Int. Cl. H03L 5/00

(52) U.S. Cl. 327/333

(57) ABSTRACT

Multistage signal amplification, including level translation, improves signal integrity, e.g., slew rate, complementary signal delay and duty cycle performance, by mirroring complementary output current in an output stage based on a signal developed in an input stage pull-up network. A multistage amplifier may comprise a first stage comprising a differential input circuit coupled, respectively, between first and second inputs and first and second nodes, wherein the first node is coupled to a first pull-up circuit controlled by the first node and the second node is coupled to a second pull-up circuit controlled by the second node; and a second stage comprising a complementary output circuit coupled, respectively, between first and second nodes and first and second outputs, wherein a current mirror sinks essentially the same current at the first output as is sourced at the second output and vice versa. The pull-up network may further comprise a cross-coupled pull-up circuit.

### TECHNICAL FIELD

The present invention generally relates to integrated circuits in the field of signal amplification, including level translation. More particularly, the invention relates to integrated circuits for controlling the slew rate, complementary delay and duty cycle of amplified signals, which may be converted from one level to another.

### BACKGROUND

Level translators are widely used in mixed signal integrated circuits to shift or translate single-ended or differential input signal levels to other single-ended or differential input signal levels. Conventional level translators generally rely on cross-coupled pull-up transistor circuits to convert input signal levels to output signal levels. Problems introduced by these and other conventional translator circuits include a lack of control of slew rate, duty cycle and complementary signal delay/shift. The break-before make (i.e. a transistor turns off before another turns on) operation of conventional translator circuits results in non-overlapping complementary signals that negatively impact performance.

FIG. 1 illustrates a well known level translator circuit. Such a circuit may be used, for example, to convert current mode logic (CML) levels to complementary Metal Oxide Semiconductor (CMOS) logic levels. As shown in level translator circuit 100, a differential input signal is applied to differential inputs IN1 and IN2. The differential inputs are coupled to the gate terminals of NMOS transistors N101, N102, which provide current amplification of the differential inputs. The drain terminal of NMOS transistor N101, identified as node 1, is coupled to the drain terminal of PMOS transistors P101 and the gate terminals of PMOS transistors P102 and P103. The drain terminal of NMOS transistor N102, identified as node 2, is coupled to the drain terminal of PMOS transistors P102 and the gate terminals of PMOS transistors P101 and P104. The drain terminals of PMOS transistors P101, P102 are cross-coupled to each others gate terminals. PMOS transistors P101, P102 serve to change the input level to the output level by pulling the node having a higher voltage up to VDD. Supply voltage VDD is coupled to the source terminals of PMOS transistors P101, P102, P103 and P104. Complementary output terminals OUT1 and OUT2 are coupled, respectively, to the drain terminals of PMOS transistors P103, P104. NMOS transistors N101, N102 are biased by current source 1100 while PMOS transistors P103, P104 are biased, respectively, by current sources 1101, 1102. The non-overlapping nature of nodes 1 and 2 switching between high and low distorts the duty cycle at output terminals OUT1 and OUT2.

In discussing operation of circuits herein, signals are referred to high (H) and low (L), indicating that H has a higher voltage potential than L. When differential input signal IN1/IN2 is H/L, NMOS transistor N101 is turned on stronger than NMOS transistor N102. As a result, node 1 is coupled to ground GND. This turns on PMOS transistors P102 and P103, which couple node 2 and output OUT1 to supply voltage VDD. Since node 2 is coupled to voltage source VDD, PMOS transistors P101, P104 are off, which couples output OUT2 to ground GND.

When differential input signal IN1/IN2 is L/H, NMOS transistor N102 is turned on stronger than NMOS transistor N101. As a result, node 2 is coupled to ground GND. This turns on PMOS transistors P101 and P104, which couple node 1 and output OUT2 to supply voltage VDD. Since node 1 is coupled to voltage source VDD, PMOS transistors P102, P103 are off, which couples output OUT1 to ground GND.

FIG. 2 illustrates operation of cross-coupled level translator circuit 100 shown in FIG. 1. FIG. 2 shows several problems with the operation of this circuit. While transitions of differential inputs IN1, IN2 occur simultaneously, the transitions at nodes 1, 2 and complementary output OUT1, OUT2 do not occur at the same time due to a delay or shift in transition. Further, the slew rates of rising and falling edges are asymmetrical. As a result, the duty cycle of complementary output signal OUT1, OUT2 is distorted from the duty cycle of differential input signal IN1, IN2 and complementary signals OUT1, OUT2 are shifted (delayed) relative to one another. Further, process variations exacerbate the duty cycle distortion and complementary signal delay/shift.

FIG. 3 illustrates another well-known level translator circuit similar to the circuit shown in FIG. 1. In level translator circuit 300, the addition of NMOS transistors N303, N304, creating output inverters P103, N303 and P104, N304, results in faster switching times at outputs OUT1, OUT2. However, as shown in FIG. 4, performance remains problematic. FIG. 4 illustrates operation of cross-coupled level translator circuit 300 shown in FIG. 3. Again, while transitions of differential inputs IN1, IN2 occur simultaneously, the transitions at nodes 1, 2 and complementary output OUT1, OUT2 do not occur at the same time due to a delay or shift in transition. Further, the slew rates of rising and falling edges at nodes 1 and 2 are asymmetrical. As a result, the duty cycle of complementary output signal OUT1, OUT2 is distorted from the duty cycle of differential input signal IN1, IN2 and complementary signals OUT1, OUT2 are shifted (delayed) relative to one another. Further, process variations exacerbate the duty cycle distortion and complementary signal delay/shift.

Therefore, there is a need to improve the signal integrity of amplified signals to minimize distortion caused by variations in slew rate, complementary signal delay and duty cycle.

### SUMMARY

This Summary is provided to introduce concepts in a simplified form. These concepts are described in greater detail below in the section entitled Detailed Description Of Illustrative Embodiments. This Summary is not intended to identify key or essential features of the claimed subject matter, nor limit the scope thereof.

The present invention provides for multistage signal amplification, including level translation, with improved slew rate, duty cycle and/or complementary signal delay performance by mirroring complementary output current in an output stage based on a signal developed in an input stage pull-up network. An amplifier in accordance with some embodiments of the invention may comprise, for example: a first stage comprising a differential input circuit coupled, respectively, between first and second inputs and first and second nodes, wherein the first node is coupled to a first pull-up circuit controlled by the first node and the second node is coupled to a second pull-up circuit controlled by the second node; and a second stage comprising a complementary output circuit coupled, respectively, between first and second nodes and first and second outputs, wherein a current mirror sinks essentially the same current at the first output as is sourced at the second output and vice versa.

An amplifier in accordance with some embodiments of the invention may comprise, for example: a first input circuit coupled between a first input and a first node; a second input circuit coupled between a second input and a second node; a first impedance circuit coupled between the first node and a voltage source; a second impedance circuit coupled between the second node and the voltage source; a first output circuit coupled between the first node and a first output; a second output circuit coupled between the second node and a second output; a first current mirror coupled between the second node and first output; and a second current mirror coupled between the first node and second output.

In some embodiments the amplifier may be configured to translate an input level to a different output level such as from CML to CMOS. In some embodiments, the amplifier may be configured to receive a single ended input while in others it may be configured to receive a differential input. In some embodiments, the amplifier may further comprise a cross-coupled pull-up circuit coupled between the first and second nodes. In some embodiments the amplifier may be configured with an NMOS input stage while in others it may be configured with a PMOS input stage.

At least some embodiments of the invention may improve signal integrity by minimizing degradation through slew rate, complementary signal delay and duty cycle of amplified signals. It may also expand applicability, e.g., by maintaining signal integrity of higher frequency signals. By eliminating the need for corrective circuitry, some embodiments of the invention may also reduce design, testing and production costs as well as die area.

### BRIEF DESCRIPTION OF THE DRAWINGS

The foregoing summary, as well as the following detailed description, is better understood when read in conjunction with the accompanying drawings. For the purpose of illustrating various aspects of multistage level translation, there is shown in the drawings exemplary implementations thereof. However, multistage level translation is not limited to the specific implementations disclosed herein.

FIG. 1 illustrates a well known cross-coupled level translator.

FIG. 2 illustrates a timing diagram for the cross-coupled level translator in FIG. 1.

FIG. 3 illustrates a well known cross-coupled level translator.

FIG. 4 illustrates a timing diagram for the cross-coupled level translator in FIG. 2.

FIG. 5, in accordance with some embodiments of the invention, illustrates an exemplary implementation of a multistage level translator with an NMOS input stage.

FIG. 6 illustrates a timing diagram for the multistage level translator in FIG. 5.

FIG. 7, in accordance with some embodiments of the invention, illustrates an exemplary implementation of a multistage level translator with a PMOS input stage.

### DETAILED DESCRIPTION OF ILLUSTRATIVE EMBODIMENTS

Reference will now be made to embodiments of the present technology for multistage level translation, examples of which are illustrated in the accompanying drawings. While the technology for multistage level translation will be described in conjunction with various embodiments, it will be understood that the embodiments are not intended to limit the present technology. On the contrary, the present technology is intended to cover alternatives, modifications, and equivalents, which may be included within the spirit and scope the various embodiments as defined by the appended claims. In addition, in the following detailed description, numerous specific details are set forth in order to provide a thorough understanding of the present technology. However, the present technology may be practiced without these specific details. In other instances, well known methods, procedures, components, and circuits have not been described in detail as not to unnecessarily obscure aspects of the embodiments presented.

Unless specifically stated otherwise, terms such as “sampling,” “latching,” “determining,” “selecting, “storing,” “registering,” “creating,” “including,” “comparing,” “receiving,” “providing,” “generating,” “associating,” and “arranging”, or the like, refer to the actions and processes of an electronic device that manipulates and transforms data represented as physical (electronic) quantities within the electronic device.

Certain terms are used throughout the following description and claims to refer to particular system components and configurations. As one skilled in the art will appreciate, various skilled artisans and companies may refer to a component by different names. The discussion of embodiments is not intended to distinguish between components that differ in name but not function. In the following discussion and in the claims, the terms “including” and “comprising” are used in an open-ended fashion, and thus should be interpreted to mean “including, but not limited to . . . . ” Also, the term “couple” or “couples” is intended to mean either an indirect or direct electrical connection. Thus, if a first device couples to a second device, that connection may be through a direct electrical connection or though an indirect electrical connection via other devices and connections. Furthermore, the term “information” is intended to refer to any data, instructions, or control sequences that may be communicated between components of a device. For example, if information is sent between two components, data, instructions, control sequences, or any combination thereof may be sent between the two components.

The present invention provides for multistage signal amplification, including level translation, with improved slew rate, duty cycle and/or complementary signal delay performance by mirroring complementary output current in an output stage based on a signal developed in an input stage pull-up network. An amplifier in accordance with some embodiments of the invention may comprise, for example: a first stage comprising a differential input circuit coupled, respectively, between first and second inputs and first and second nodes, wherein the first node is coupled to a first pull-up circuit controlled by the first node and the second node is coupled to a second pull-up circuit controlled by the second node; and a second stage comprising a complementary output circuit coupled, respectively, between first and second nodes and first and second outputs, wherein a current mirror sinks essentially (i.e. ±10%) the same current at the first output as is sourced at the second output and vice versa.

An amplifier in accordance with some embodiments of the invention may comprise, for example: a first input circuit coupled between a first input and a first node; a second input circuit coupled between a second input and a second node; a first impedance circuit coupled between the first node and a voltage source; a second impedance circuit coupled between the second node and the voltage source; a first output circuit coupled between the first node and a first output; a second output circuit coupled between the second node and a second output; a first current mirror coupled between the second node and first output; and a second current mirror coupled between the first node and second output.

In some embodiments the amplifier may be configured to translate an input level to a different output level such as from CML to CMOS. In some embodiments, the amplifier may be configured to receive a single ended input while in others it may be configured to receive a differential input. In some embodiments, the amplifier may further comprise a cross-coupled pull-up circuit coupled between the first and second nodes. In some embodiments the amplifier may be configured with an NMOS input stage while in others it may be configured with a PMOS input stage.

FIG. 5, in accordance with some embodiments of the invention, illustrates an exemplary implementation of a multistage level translator with an NMOS input stage. As illustrated in FIG. 5, amplifier or level translator 500 comprises a first stage 505 and a second stage 510, 515. First stage 505 may be an input stage or an intermediate stage. Second stage 510, 515 may be an output stage or an intermediate stage. In other words, in other embodiments, additional stages may be added to level translator 500.

First stage 505 comprises a differential input circuit coupled, respectively, between first and second inputs IN1, IN2 and first and second nodes 1, 2. The differential input circuit comprises first and second input circuits. The differential input circuit may vary from one embodiment to the next. In the embodiment shown in FIG. 5, the first input circuit comprises first NMOS transistor N1 and the second input circuit comprises second NMOS transistor N2. First and second NMOS transistors N1 and N2 may be enhanced mode devices operated in the saturation region. First and second NMOS transistors N1 and N2 are biased by constant current source I, which may represent, for example, a constant transconductance bias circuit controlling a bias transistor to maintain constant current I. Since very little current flows into the gate terminals of PMOS transistors P3-P6, current flowing through the pull-up network coupled to first node 1 (first and 11th PMOS transistors in this embodiment) will be approximately the same current flowing through first NMOS transistor N1. Similarly, current flowing through the pull-up network coupled to second node 2 (second and 22nd PMOS transistors in this embodiment) will be approximately the same current flowing through second NMOS transistor N2. The combined current flowing through both pull up networks and first and second NMOS transistors N1, N2 will be approximately equal to bias current I.

First NMOS transistor N1 has its source terminal coupled (in this embodiment directly coupled) to current source I, its drain terminal coupled to first node 1 and its gate terminal coupled to first input IN1. Second NMOS transistor N2 has its source terminal coupled to current source I, its drain terminal coupled to second node 2 and its gate terminal coupled to second input IN2. First and second NMOS transistors N1, N2 are controlled by differential input IN1, IN2. First and second NMOS transistors N1, N2 act as current amplifiers in response to differential input IN1, IN2. The current combined through first and second NMOS transistors N1, N2 is limited by constant current I. Incidentally, in some embodiments, the gate of either first or second NMOS transistors N1, N2 may be coupled to a reference while the gate of the other NMOS transistor N1, N2 is coupled to a single-ended input. The reference voltage may be higher than a threshold voltage of first or send NMOS transistors N1, N2. Other embodiments employing other input circuits may likewise be configured to receive single-ended or differential inputs.

First node 1 is coupled to a first pull-up circuit controlled by first node 1 and second node 2 is coupled to a second pull-up circuit controlled by second node 2. In the embodiment shown in FIG. 5, the first pull-up circuit comprises first PMOS transistor P1 while the second pull-up circuit comprises second PMOS transistor P2. However, the first and second pull-up circuits may vary from one embodiment to the next. As shown in this particular embodiment, first PMOS transistor P1 has its source coupled to voltage source VDD while its drain and gate are both coupled to first node 1. Similarly, second PMOS transistor P2 has its source coupled to voltage source VDD while its drain and gate are both coupled to second node 2. In this embodiment, first and second pull-up circuits are configured as pull-up PMOS resistors. First pull-up transistor P1 functions as a resistor when first node 1 is less than voltage source VDD by the threshold of first pull-up transistor P1. Similarly, second pull-up transistor P2 functions as a resistor when second node 2 is less than voltage source VDD by the threshold of second pull-up transistor P2. Thus, effectively, first and second impedance circuits (in this embodiment P1, P2) are coupled, respectively, between voltage source VDD and first and second nodes 1, 2. First and second PMOS transistors P1, P2 may be enhanced mode devices. The parameters, including dimensions, of first and second PMOS transistors P1, P2 determine the voltage swing of first and second nodes 1, 2. This voltage swing is subsequently amplified in the subsequent stage. Other impedance circuits may be used in other embodiments.

Also in the first stage, an optional cross-coupled pull-up circuit may also be coupled between first and second nodes 1, 2. In the embodiment shown in FIG. 5, the cross-coupled pull-up circuit comprises eleventh 11th and twenty-second 22nd PMOS transistors P11 and P22. 11th PMOS transistor P11 has its source terminal coupled to voltage source VDD, its drain terminal coupled to first node 1 and its gate terminal coupled to second node 2. 22nd PMOS transistor P22 has its source terminal coupled to voltage source VDD, its drain terminal coupled to second node 2 and its gate terminal coupled to first node 1.

Together, first and second pull-up circuits (i.e., P1, P2 in this embodiment) and cross-coupled pull up circuit (i.e. P11, P22 in this embodiment) operate as a pull-up network to quickly pull up first or second nodes 1, 2 and conserve current in the second stage, although they may be designed and employed differently. Level translator 500 may be operated with or without the optional cross-coupled pull-up circuit. Cross coupled pull-up PMOS transistors P11, P22 serve to pull-up an opposing node to source voltage VDD. As will be discussed in greater detail with respect to the second stage 510, 515, the presence of cross-coupled pull-up transistors P11, P22 may serve to reduce power consumption, or otherwise improve performance of level translator 500.

Each second stage 510, 515 comprises an output circuit and a current mirror circuit. Second stage 510 comprises a first output circuit and a first current mirror circuit. Second stage 515 comprises a second output circuit and a second current mirror circuit. The first output circuit is coupled to and controlled by the same node, i.e., first node 1, as the second current mirror. The second output circuit is coupled to and controlled by the same node, i.e., second node 2, as the first current mirror. In the embodiment shown in FIG. 5, the first output circuit, in second stage 510, comprises fifth PMOS transistor P5 while the second output circuit, in second stage 515, comprises sixth PMOS transistor P6. Fifth PMOS transistor P5 is coupled between first node 1 and first output OUT1. Specifically, its source terminal is coupled to source voltage VDD, its drain terminal is coupled to first output OUT1 and its gate terminal is coupled to first node 1. Sixth PMOS transistor P6 is coupled between second node 2 and second output OUT2. Specifically, its source terminal is coupled to source voltage VDD, its drain terminal is coupled to second output OUT2 and its gate terminal is coupled to second node 2. The first and second output circuits may vary from one embodiment to the next.

The first current mirror circuit, in second stage 510, is coupled between second node 2 and first output OUT1. The first current mirror circuit comprises third PMOS transistor P3, third NMOS transistor N3 and fifth NMOS transistor N5. Specifically, third PMOS transistor P3 has its gate terminal coupled to second node 2, its source terminal coupled to voltage source VDD and its drain terminal coupled to the drain and gate terminals of third NMOS transistor N3 and the gate terminal of fifth NMOS transistor N5. The source terminals of the third and fifth NMOS transistors N3, N5 are coupled to ground and the drain terminal of fifth NMOS transistor N5 is coupled to first output OUT1. The second current mirror circuit, in second stage 515, is coupled between first node 1 and second output OUT2. The second current mirror circuit comprises fourth PMOS transistor P4, fourth NMOS transistor N4 and sixth NMOS transistor N6. Specifically, fourth PMOS transistor P4 has its gate terminal coupled to first node 1, its source terminal coupled to voltage source VDD and its drain terminal coupled to the drain and gate terminals of fourth NMOS transistor N4 and the gate terminal of sixth NMOS transistor N6. The source terminals of the fourth and sixth NMOS transistors N4, N6 are coupled to ground and the drain terminal of sixth NMOS transistor N6 is coupled to second output OUT2. The first and second current mirror circuits may vary from one embodiment to the next.

First stage 505 amplifies the voltage level of first and second inputs IN1, IN2, where one input may be a reference in some embodiments, to first and second nodes 1, 2. Voltage develops at first and second nodes 1, 2 as current flows through the pull-up networks coupled to them. An input signal higher in voltage potential (either first or second input IN1, IN2) generates a higher current through the input transistor it controls (N1 or N2) compared to the other transistor having a lower input. In turn, this draws more current through the pull-up network coupled to the input transistor with a higher input level. This decreases the voltage level at the node through which more current is flowing. The node with the lower potential more strongly turns on the PMOS output transistor it is coupled to.

Transistors in the first stage 505 (in this embodiment N1, N2, P1, P2, optionally P11, P22) are designed to control impedance for rise and fall time and to maintain an essentially symmetrical signal delay at first and second nodes 1, 2. Depending on the embodiment, it may or may not be desirable for the control to be symmetrical. However, in this embodiment it is presumed to be desirable to have symmetrical control. In this embodiment, any differential input at first and second inputs IN1, IN2 will be amplified essentially symmetrically.

Cross coupled pull-up PMOS transistors P11, P22 serve to pull-up an opposing node to source voltage VDD in order to more quickly and completely turn off one or the other output circuits (fifth and sixth transistors P5, P6 in this embodiment) and, therefore, first or second current mirror. As previously mentioned, cross-coupled pull-up PMOS transistors P11, P22 may be designed and employed differently compared to first and second PMOS transistors P1 and P2. For example, in some embodiments each cross-coupled transistor P11, P22 may be approximately (±10%) one-half the size of each of first and second PMOS transistors P1 and P2 so that each cross-coupled transistor P11, P22 cannot over drive first and second PMOS transistors P1, P2.

Completely turning off first or second output transistors P5, P6 may, for example, reduce power consumption. When level translator 500 is operated without cross coupled pull-up PMOS transistors P11 and P22, both fifth and sixth PMOS transistors P5, P6, and therefore first and second current mirrors may all be on and drawing current to some degree. Nonetheless, amplifier 500 operates properly because first and second current mirror circuits mirror any current that may be flowing in fifth and sixth PMOS transistors P5, P6. Appropriate symmetry exists between fifth NMOS and PMOS transistors N5, P5 and sixth NMOS and PMOS transistors N6, P6. As a result, first and second output transistors OUT1, OUT2 source and sink essentially the same current and produce essentially the same slew rates. Additional improvements, besides cross-coupled PMOS transistors P11, P22, may be made to amplifier 500. Such improvements may depend on the particular embodiment. Similarly, device parameters may vary from one embodiment to the next to control, for example, delay times, slew rates and, therefore, duty cycle. Depending on the embodiment, it may be desirable to faithfully maintain or to vary input signal parameters, both of which may be accomplished through device parameters.

Second stage 510, 515 further amplifies the voltage level of first and second nodes 1, 2, essentially symmetrically controls the rise/fall time and signal delay at first and second outputs OUT1, OUT2. Second stage 510, 515 also may convert the input level, e.g., CML, at first and second inputs IN1, IN2 to output level (e.g. CMOS VDD to GND) at first and second outputs OUT1, OUT2. Obviously, other embodiments may translate other signal levels. In the second stage 510, 515, first and second output circuits (in this embodiment fifth and sixth PMOS transistors P5, P6) comprise a complementary output circuit coupled, respectively, between first and second nodes 1, 2 and first and second outputs OUT1, OUT2. Fifth and sixth PMOS transistors P5, P6 essentially (i.e. ±10%) symmetrically control the rise time of first and second outputs OUT1, OUT2. With regard to controlling fall times, the first current mirror, assuming proper matching of transistors, causes fifth NMOS transistor N5 to sink essentially the same current from first output OUT1 as is sourced by second output circuit (sixth PMOS transistor P6) to second output OUT2. Similarly, the second current mirror, assuming essentially proper matching of transistors, causes sixth NMOS transistor N6 to sink essentially the same current from second output OUT2 as is sourced by first output circuit (fifth PMOS transistor P5) to first output OUT2.

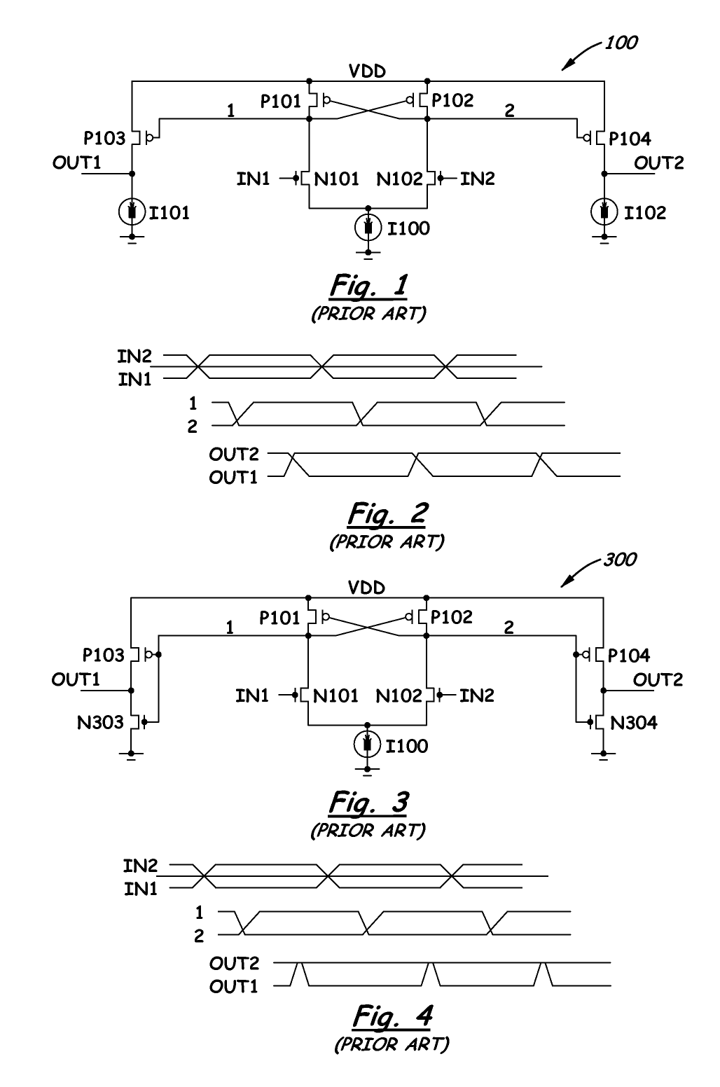

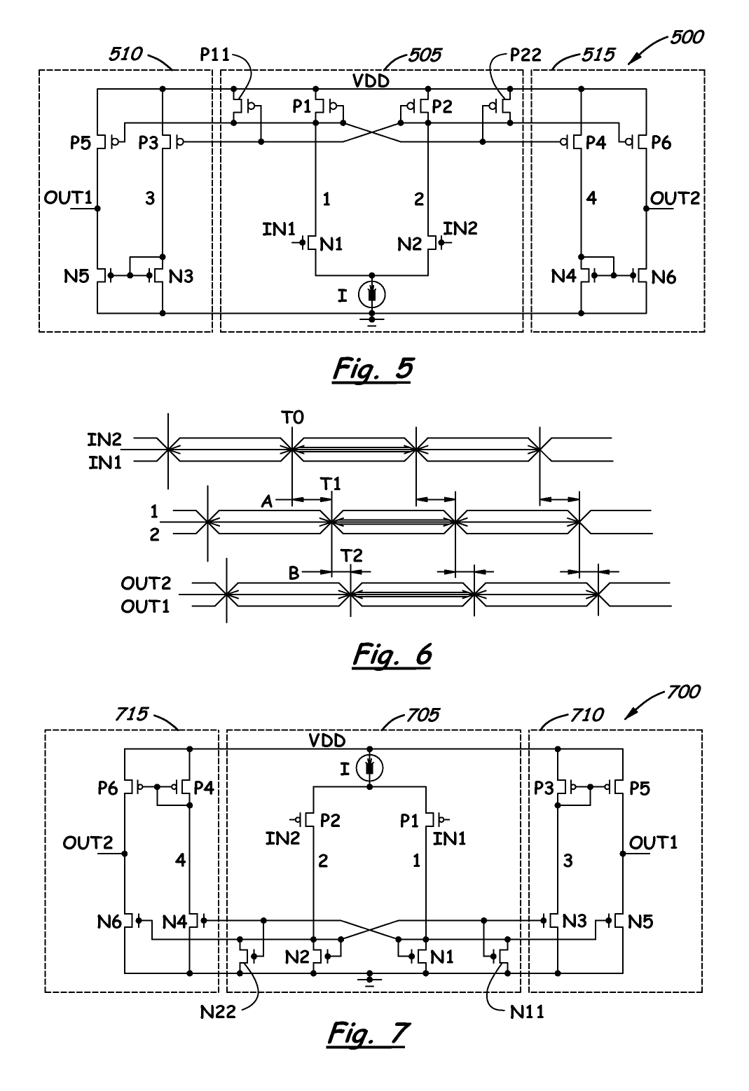

By maintaining essentially symmetrical rising and falling edge rates (slew rates) and complementary signal delay at first and second nodes 1, 2 and first and second outputs OUT1, OUT2, both stages 505, 510, 515 minimize distortion to better maintain the integrity (e.g. duty cycle) of single-ended and differential input signals received at first and second inputs IN1, IN2. Reference may be made to FIG. 6, relative to FIGS. 2 and 4, to visualize the improvement in signal integrity over some examples of the prior art. FIG. 6 illustrates a timing diagram for the multistage level translator in FIG. 5. By maintaining slew rate and signal delay, transition times T0, T1 and T2 are the same for rising and falling edges of first and second nodes 1, 2 and first and second outputs OUT1, OUT2. Of course delay time A (between a transition in first and second inputs IN1, IN2 and first and second nodes 1, 2) as well as delay time B (between a transitions in first and second nodes 1, 2 and first and second outputs OUT1, OUT2) may be appropriately designed and implemented in accordance with specifications for various embodiments of the subject matter described herein. It should be noted that the levels shown for first and second nodes 1, 2 in FIG. 6 are not necessarily translated levels. Where amplifier 500 is used as a level translator, translation may be achieved in the output of second stage 510, 515. First stage 505 may be used to avoid asymmetrical switching.

FIG. 7, in accordance with some embodiments of the invention, illustrates an exemplary implementation of a multistage level translator with a PMOS input stage. FIG. 7 illustrates amplifier 500 shown in FIG. 5 using a PMOS input stage instead of an NMOS input stage. Operation of amplifier 700 is substantially similar to operation of amplifier 500. In some embodiments, both NMOS and PMOS input stages may be used in parallel. This may improve signal tolerances in such embodiments.

Embodiments of the present invention may be utilized in a wide variety of applications requiring single ended or differential signal amplification or interface circuitry (e.g. level translator). Embodiments of the present invention may, for example, be used in circuits designed to shift or translate levels between input and output signals, to control or adjust/correct signal slew rate as in controller or driver circuitry, to correct baseline wander in a communication signal as in a receiver, etc. For example, first stage 505 could be a pre-driver while second stage 510, 515 is a driver stage. Not all embodiments of the invention will operate symmetrically. Some embodiments may be designed to be asymmetrical, as in the case of embodiments designed to correct distortion or otherwise modify input signals. The subject matter described herein may be designed, tested and manufactured in numerous technologies, including but not limited to CMOS, Bipolar and BiCMOS. While not show or discussed herein, transistors may also have bulk terminals. In some embodiments, in order to avoid a body effect (i.e. threshold variation), the bulk and source terminals of one or more transistors in any embodiment may be connected together, e.g., by constructing transistor(s) using a deep n-well process to connect the bulk to the source.

The inventions described herein may provide numerous benefits. At least some embodiments of the invention may improve signal integrity by minimizing degradation through slew rate, complementary signal delay and duty cycle of amplified signals. It may also expand applicability, e.g., by maintaining signal integrity of higher frequency signals. By eliminating the need for corrective circuitry, some embodiments of the invention may also reduce design, testing and production costs as well as die area.

While the present invention has been described with respect to a limited number of embodiments, those skilled in the art will appreciate numerous modifications and variations there from. It is intended that the appended claims cover all such modifications and variations as fall within the true spirit and scope of this present invention.

What is claimed:

1. An amplifier comprising:
a first input circuit coupled between a first input and a first node;
a second input circuit coupled between a second input and a second node;
a first impedance circuit coupled between the first node and a voltage source;
a second impedance circuit coupled between the second node and the voltage source;
a first output circuit coupled between the first node and a first output;
a second output circuit coupled between the second node and a second output;
a first current mirror coupled between the second node and first output; and
a second current mirror coupled between the first node and second output.

2. The amplifier of claim 1, further comprising:
a cross-coupled pull-up circuit coupled between the first and second nodes.

3. The amplifier of claim 2, wherein the cross-coupled pull-up circuit comprises a first PMOS transistor having its source coupled to the voltage source, drain coupled to the first node and gate coupled to the second node and a second PMOS transistor having its source coupled to the voltage source, drain coupled to the second node and gate coupled to the first node.

4. The amplifier of claim 1, wherein the amplifier circuit is configured to translate an input level to a different output level.

5. The amplifier of claim 4, wherein the input level is CML and the output level is CMOS.

6. The amplifier of claim 1, wherein the amplifier circuit is configured to receive a differential input.

7. The amplifier of claim 1, wherein the amplifier circuit is configured to receive a single-ended input at the first or second input with the other input coupled to a reference signal.

8. The amplifier of claim 1, wherein the first input circuit comprises an NMOS transistor having its gate coupled to the first input, source coupled to a bias current source and drain coupled to the first node.

9. The amplifier of claim 1, wherein the first impedance circuit comprises a PMOS transistor having its gate and drain coupled to the first node and source coupled to the voltage source.

10. The amplifier of claim 1, wherein the first output circuit comprises a PMOS transistor having its gate coupled to the first node, source coupled to the voltage source and drain coupled to the first output.

11. The amplifier of claim 1, wherein the first current mirror comprises a PMOS transistor having its gate coupled to the second node, source coupled to the voltage source and drain coupled to a drain and gate of a first NMOS transistor and a gate of a second NMOS transistor, wherein the sources of the first and second NMOS transistors are coupled to ground and a drain of the second NMOS transistor is coupled to the first output.

12. An amplifier comprising:
a first stage comprising a differential input circuit coupled, respectively, between first and second inputs and first and second nodes, wherein the first node is coupled to a first pull-up circuit controlled by the first node and the second node is coupled to a second pull-up circuit controlled by the second node; and
a second stage comprising a complementary output circuit coupled, respectively, between first and second nodes and first and second outputs, wherein a current mirror sinks essentially the same current at the first output as is sourced at the second output and vice versa.

13. The amplifier of claim 12, wherein the first and second pull-up circuits each comprise a pull-up transistor configured as a pull-up resistor.

14. The amplifier of claim 13, wherein the first pull-up circuit comprises a PMOS transistor having its gate and drain coupled to the first node and source coupled to a voltage source.

15. The amplifier of claim 12, wherein the first stage further comprises a cross-coupled pull-up circuit coupled between the first and second nodes.

16. The amplifier of claim 14, wherein the cross-coupled pull-up circuit comprises a first PMOS transistor having its source coupled to a voltage source, drain coupled to the first node and gate coupled to the second node and a second PMOS transistor having its source coupled to the voltage source, drain coupled to the second node and gate coupled to the first node.

17. The amplifier of claim 12, wherein the amplifier is configured to translate an input level to a different output level.

18. The amplifier of claim 16, wherein the input level is CML and the output level is CMOS.

19. The amplifier of claim 12, wherein the first stage is configured to receive a differential input.

20. The amplifier of claim 12, wherein the amplifier is configured to receive a single-ended input at the first or second input with the other input coupled to a reference signal.
